(19) United States
(12) Patent Application Publication
(10) Pub. No.: US 2005/0226806 A1
(43) Pub. Date: Oct. 13, 2005

(54) Photonic crystals having a skeleton structure

(76) Inventors: Frank Marlow, Berlin (DE); Wenting Dong, Yang Pu District Shanghai (CN)

Correspondence Address: NORRIS, MCLAUGHLIN & MARCUS, PA, 875 THIRD STREET, 18TH FLOOR, NEW YORK, NY, 10022, US

(21) Appl. No.: 10/503,341

(22) PCT Filed: Jan. 29, 2003
(86) PCT No.: PCT/EP03/00861

§ 371 Date: Apr. 29, 2005

(30) Foreign Application Priority Data
Feb. 1, 2002 (DE) 102-04-318.3

(51) Int. Cl. C01G 23/047; C30B 7/00; C30B 21/02; C30B 28/06

(52) U.S. Cl. 423/610; 117/68; 117/69; 117/71

(57) ABSTRACT

The invention relates to a class of photonic crystals that are similar to the known inverse opals while being characterized by so far not known band gaps or larger pseudo band gaps, especially between the 5^{th} and 6^{th} band and/or between the 8^{th} and 9^{th} band. The invention further relates to a method for producing said photonic crystals and to the use thereof as larger resonators, matrices for optical guides, opalescent pigments, beam splitters, spectral filters or as components of such devices.

The invention relates to a class of photonic crystals which are similar to the known inverse opals, but until now have had unknown bandgaps or greater pseudo bandgaps, in particular between the fifth and sixth bands, and/or between the eighth and ninth bands. The invention furthermore relates to a method for production of photonic crystals and their use as a laser resonator, a matrix for optical waveguides, an opalescent pigment, a beam splitter, a spectral filter or as a component of such apparatuses.

### BACKGROUND TO THE INVENTION

Photonic crystals are materials in which the refractive index is varied periodically in three dimensions, with lattice constants in the region of the light wavelength being of particular interest. The periodic variation of the material is applied to the light waves which propagate in these media (see, for example, J. D. Joannopoulos, R. D. Meade, J. N. Winn, Photonic Crystals: Molding the flow of light. Princeton University Press, 1995. It has been found that these periodically modulated waves cannot be produced for any frequency for a selected direction. Particularly if the wavelength of these waves virtually matches the network plane separations in the photonic crystal, the propagation is highly modified by multiple scatter, and its frequency is decreased or increased. This results in gaps in the frequency scale, in which there is no mathematical solution for the propagation problem of electromagnetic waves in the periodic material. Depending on whether these gaps occur for all directions of electromagnetic waves, or only in a restricted range of directions, these frequency gaps are referred to as bandgaps or pseudo bandgaps. Their calculation requires the processing of the wave equation for the electromagnetic field, for which purpose methods have been developed which are used in a similar manner to the Schrodinger equation in a periodic potential (J. D. Joannopoulos, R. D. Meade, J. N. Winn, Photonic Crystals: Molding the flow of light. Princeton University Press, 1995; K. Busch, S. John, Phys. Rev. E 58 (1998) 3896; S. G. Johnson, J. D. Joannopoulos, Optics Express 8 (2000) 173).

Photonic crystals are of major interest for use in optical components, such as those which are used in the communications industry. In particular, materials with large optical bandgaps allow novel optical functionalities (F. Marlow, Nachrichten Chem. [Information Chem.] 49 (2001) 1018).

Photonic crystals may be produced on the basis of spherical packages. However, dense packaging of spheres with a high refractive index never has a complete bandgap, although its inverse structure, with closely arranged spherical cavities in a material with a high refractive index, may have. A production method has been derived from this in which original spherical packaging is used as a molding (negative mold) for the inverse structure, which will be referred to in the following text as the remaining volume structure (RVS) when it completely fills the molding (Y. A. Vlasov, N. Yao, D. J. Norris, Adv. Mater. 11 (1999) 165; A. Zakhidov et al. U.S. Pat. No. 6,261,469). Furthermore, production methods have been found for shell structures, in which the molding is filled with a layer of a material (J. E. Wijnhoven, W. L. Vos, Science, 281 (1998) 802).

Remaining volume structures are predominantly concave, since they are derived from a convex mold (spherical packaging). This characteristic can be described as follows by the mean radius of curvature <\overline{R}> of a structure whose total surface area is A:

$$〈 R 〉 = \frac{1}{A} {\int \int }_{A} ⅆ A \overline{R} ( x )$$

$$2 / \overline{R} ( x ) = 1 / {R}_{1} + 1 / {R}_{2}$$

In this case, R₁ and R₂ are the two extreme radii of curvature of the surface at the point x. By definition, they should be positive if the center of the circle of curvature is located in the dense material. Thus, for example, a polystyrene opal composed of spheres whose radius is Rₚₛ has a mean radius of curvature of <R>=Rₚₛ (that is to say a positive <R>), and a corresponding ideal RVS (inverse opal) has a negative <R> of <R>=−Rₚₛ. Structures with a positive <R> are referred to as being predominantly convex, while those with a negative <R> are referred to as being predominantly concave.

However, predominantly concave structures are subject to a range of problems, since structures such as these generally have sharp edges (that is to say relatively small regions with an extremely small positive radius of curvature). These edges connect the concave surface elements. The behavior of the electromagnetic fields on these edges is extremely complicated. This is evident in calculation difficulties (convergence problems) and in a strong dependency on the precise edge shape, which restricts the direct control options for the optical characteristics. Furthermore, the implementation options for such structures are restricted, since they generally require complete pore fillings (in the original opal) as well as very precise control of the exact edge shape.

### FIGURE DESCRIPTION

FIG. 1: Band structure for a model system composed of cylinders which connect the center points of the octahedral and tetrahedral cavities of a hexagonally dense spherical packaging (with fcc lattices) to one another. The frequency is expressed in the unit c/a, where c is the speed of light in a vacuum and a is the edge length of the usual cubic unit cell (with four times the volume of the primitive cell) of the fcc lattice. The wave vector k varies within the Brillouin zone from X through U, L, Λ, x, W, K back to Λ. In comparison to standard representations, such as that in J. D. Joannopoulos, R. D. Meade, J. N. Winn in Photonic Crystals: Molding the flow of light, Princeton University Press, 1995, page 80, the link between the K point and the Λ point was additionally considered.

FIG. 2: Scanning electron microscope record (acceleration voltage 25 kV, 40 000 times electron microscope magnification) of a skeleton structure. The connecting pieces are cylindrical and have a cylinder radius of about 0.06 a.

### DESCRIPTION OF THE INVENTION

The invention is based on the object of providing photonic crystals having predominantly convex structures, as well as a method for their production which, on the basis of opal structures, allows the variation of the structure parameters, in particular of the cylinder thickness, and which allows the reproducible synthesis of photonic crystals with a broader application range.

A first aspect of the invention relates to a photonic crystal whose structure is topologically equivalent to the inverse structure of a predominantly convex molding, characterized in that this crystal
has a predominantly convex structure, and
has a bandgap or pseudo bandgap between the fifth and sixth bands, and/or
has a bandgap or pseudo bandgap between the eighth and ninth bands,
   with at least one bandgap or pseudo bandgap being greater than that of the inverse structure, which is composed of the same material as the photonic crystal, of the predominantly convex molding.

A second aspect of the invention relates to a method for production of a photonic crystal, based on a predominantly convex molding, comprising the following steps:
(A) penetration of a matrix precursor into the cavities in the convex molding;
(B) conversion of the matrix precursor to the matrix former;
(C) redistribution of the matrix precursor/matrix former which is located in the cavities and/or of their intermediate stages while maintaining the topology;
(D) removal of the molding.

A third aspect of the invention relates to a photonic crystal which can be obtained by the method described above.

A fourth aspect of the invention relates to use of the photonic crystal according to the invention as a laser resonator, a matrix for optical waveguides, an opalescent pigment, a beam splitter or a spectral filter, or as a component of the apparatuses mentioned above.

Preferred embodiments of the invention can be found in the dependent claims.

The photonic crystals according to the invention will be referred to as skeleton structures, since they can be formed from cylindrical or deformed cylinders or similar individual parts. These individual parts are convex structures, which are held together only by small concave fillets.

For the production of the structures according to the invention, it is significant that incomplete filling of the molding enlarges the bandgaps. Furthermore, when using suitable production methods, parts of these structures may mathematically overlap the molding if the final phase for production of the skeleton structures takes place at the same time as the removal of the molding.

The basic predominantly convex moldings, which are used as a “negative mold” for the photonic structures according to the invention, have an opal structure. According to the methods which are known from the prior art for the production of opals, for example sedimentation, the moldings can be obtained using a large number of materials. The critical factor is that the materials that are used can be shaped to form correspondingly small spheres. Polymers and amorphous inorganic oxides have been found to be particularly suitable, which are chosen from the group comprising polystyrene, polymethylmethacrylate (PMMA), polydivinylbenzene, poly(styrene-co-divinylbenzene), melamine resins and silicon dioxide.

Preferred substances which form the structures according to the invention (therefore referred to as matrix formers) are oxides, semiconductors, metals and polymers, which are available in the form of matrix precursors, preferably in solution. Suitable matrix precursors comprise at least one compound which is chosen from the group comprising:
(i) Metal alkoxides with the general formula Mⁿ⁺(OR)ₙ, where R is a branched or unbranched hydrocarbon group with 1 to 12, preferably 2 to 8, and particularly preferably 3 to 4, carbon atoms and M is a metal which is chosen from the groups IIb, IIIa, IIIb, IVa, IVb and VIIIb in the periodic table of the elements;
(ii) Metal halides or nitrates with the general formula Mⁿ⁺(X⁻)ₙ, where X is a halide ion chosen from F⁻, Cl⁻, Br⁻ and I⁻ or a nitrate ion (NO₃⁻), and M is a metal which is chosen from the groups IIb, IIIa, IIIb, IVa, IVb and VIIIb in the periodic table of the elements.

Examples of compounds such as these are titanium isopropoxide, aluminum chloride, aluminum nitrate, iron(III) chloride and iron(III) nitrate.

Suitable solvents or additives for the compounds mentioned above are preferably alcohols or their mixtures, which are chosen from the group comprising methanol, ethanol, 1-propanol or 2-propanol and 1-, 2- or tert-butanol. The use of water as a solvent or additive, either on its own or in a mixture with the solvents -mentioned above, may be advantageous. In the case of liquid precursors, the use of a solvent or additive can often be completely dispensed with. The flowing characteristics of the precursor and the resultant structure parameters are dependent on the solvent or the additive.

The conversion of the matrix precursors to matrix formers is carried out after their penetration into the cavities in the molding by calcination, condensation, hydrolysis, oxidation, reduction or drying, or combinations of the reactions mentioned above.

The precise reaction conditions which are required for conversion of the matrix precursors to the matrix formers are dependent on the nature of the chosen matrix precursors. For example, the use of metal alkoxides as precursors for conversion by hydrolysis and condensation may therefore require contact with the moisture in the air.

However, the critical factor in all cases is that the cavities in the molding are not filled completely by shrinkage of the matrix precursors/formers, such shrinkage taking place during the conversion of the matrix precursor to the matrix former.

This shrinkage itself allows deliberate redistribution of the matrix precursors/formers into defined volume segments of the cavities in the molding, forming the desired skeleton structure.

The critical factor for the achievable range of structure parameters is in many cases that the redistribution of the matrix precursor (C) and the removal of the molding (D) take place simultaneously.

In this case, gel-like intermediate stages of the inverse structure in the pores of the opal are preferably used which occur, for example as a result of condensation, during the conversion of the matrix precursors to the matrix formers.

Steps (B) and (C) may be carried out simultaneously, particularly when using gel-like intermediate stages such as these.

Another option is to use other known production processes for inverse opals (for example A. Zakhidov et al., U.S. Pat. No. 6,261,469), in which case an inverse opal of lower density is produced first of all, which is then subjected to a subsequent shrinkage or heat-treatment process, which changes the form of the individual structure elements, while maintaining the topology of the structure. The use of etching processes is also one possible way to subsequently form the inverse opal.

The removal of the molding (C) from the skeleton structure can be carried out by calcination, etching or dissolving.

Depending on the respective molding and matrix precursors/formers, the calcination process is carried out at temperatures from 450 to 700° C., preferably 500 to 650° C., and particularly preferably 550 to 600° C. within a time period of 2 to 12 h, preferably 4 to 10 h, and particularly preferably 5 to 8 h. In this case, it has been found to be advantageous for the actual calcination process to be preceded by a heating-up phase with a heating rate of 0.8 to 10° C./min, preferably 2 to 8° C./min, and particularly preferably 5 to 6° C., and for cooling down to be carried out at a cooling-down rate of 1 to 15° C./min, preferably 4 to 12° C./min, and particularly preferably 8 to 10° C./min. The calcination process may be carried out in a large number of different ovens. Suitable ovens are described by the prior art, and have been known to those skilled in the art for a long time.

The removal of the moldings by etching or dissolving is preferably carried out when the moldings which have been used are composed of materials with high thermal stability. For example, a molding composed of silicon dioxide, which cannot be removed by calcination owing to its very high thermal stability, can be removed from the skeleton structure with the aid of hydrofluoric acid (HF). However, this is dependent on the matrix formers not being attacked by hydrofluoric acid. The photonic crystals which are produced by the method according to the invention are characterized in that these crystals
have a predominantly convex structure, and
have a bandgap or pseudo bandgap between the fifth and sixth bands, and/or
have a bandgap or pseudo bandgap between the eighth and ninth bands.

The chemical composition of the photonic crystals according to the invention is admittedly similar to that of known RVS or shell structures, but they have a considerably different three-dimensional form.

The crystals according to the invention, which are produced by preferably incomplete filling of the cavities in a predominantly convex molding (for example a spherical arrangement), have at least one complete bandgap or a pseudo bandgap. A bandgap/pseudo bandgap is in this case larger than the bandgap or pseudo bandgap of the inverse structure, which is composed of the same material as the photonic crystal, of the predominantly convex molding.

In a further embodiment according to the invention, the photonic crystals have two or more bandgaps at the same time.

The bandgaps were verified by means of model calculations. The calculations were carried out with the aid of the MIT Photonic Bands (MPB) Software (available as freeware at http://ab-initio.mit.edu/mpb), which is known from the prior art (S. G. Johnson and J. D. Joannopoulos in Optics Express 8 (2000) 173). Typically, 10 bands were calculated with the parameters grid-size (16 16 16), mesh-size 7 and tolerance 10⁻⁷.

Topologically, the skeleton structures of the photon crystals according to the invention are the same as the known inverse structures of opals or sintered opals (“topologically equivalent”), if this is RVS or variations of it (for example with rounded edges). In consequence, (a) the lattice type is the same, (b) the existence of links (windows) between cavities does not differ, and (c) the existence of links between the structure crossings is unchanged. Differences in the skeleton structures and in the RVS occur particularly in the form of links between the structure crossings (a circular cross section or a cross section similar to a circle in the skeleton structures), and in the form of the structure crossings.

Accumulations of dense material (matrix formers) in the largest cavities in the molding, for example in the octahedral, tetrahedral and possibly other intermediate spaces in spherical packages which provide the shape are referred to as structure crossings. These intermediate spaces must be formed by at least four spheres.

Cavities in the skeleton structures are in this case preferably intended to mean cavities which are filled with air, although they may also be filled with a material with a low refractive index (lower than that of the structure).

The structure is the totality of the accumulations of dense material (matrix formers).

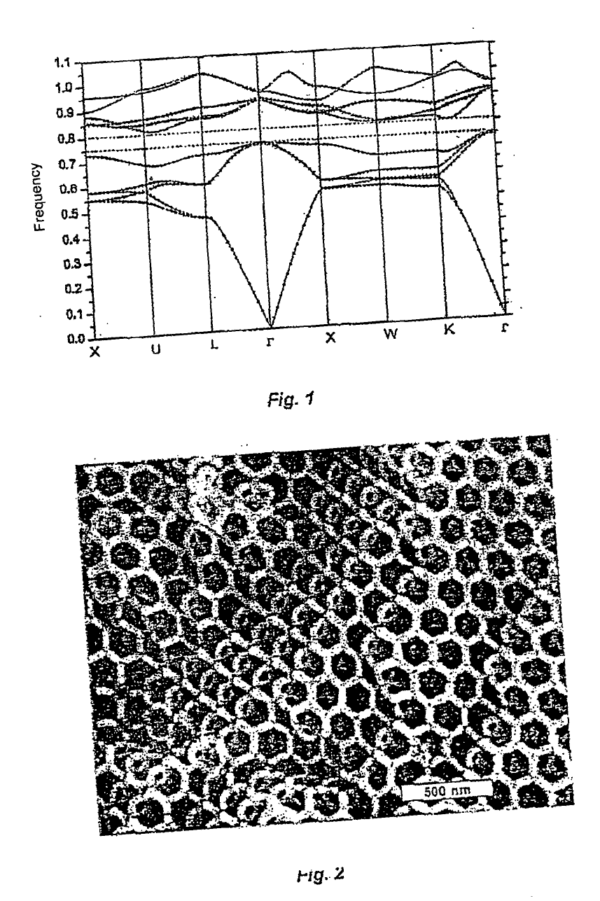

Model calculations on skeleton structures show that a bandgap occurs between the fifth and sixth bands instead of or in addition to the known bandgap between the eighth and ninth bands (“5-6 materials” or “5-6/8-9 materials”, respectively). In this case, skeleton structures were used which are formed from cylinders and which connect the center points of the octahedral and tetrahedral cavities in an opal with an fcc structure (cubic surface-centered lattice) to one another. The bandgap between the fifth and sixth bands occurs above a refractive index contrast n (ratio of the refractive index of the structure to the refractive index of the cavities) of 2.9 in optimized structures (see FIG. 1). This is characterized by a maximum of the fifth band at the gamma point, and by a minimum of the sixth band within the Brillouin zone at about k=0.82 k(K) when, for example, a skeleton structure composed of cylinders with an optimized radius is used. In this case, k(K) is the quasi impulse at the K point of the Brillouin zone (for a definition of the K point and gamma point, see O. Madelung, Festkörpertheorie [Solid body theory], Springer Berlin, 1972, page 87). Until now, this bandgap has neither been predicted nor found for RVS nor for a shell structure.

Furthermore, a number of bandgaps below the tenth band (that is to say at relatively low frequencies) occur simultaneously in the fcc lattice skeleton structures which are composed of cylinders. At the same time as the bandgap between the fifth and sixth bands, the bandgap between the eighth and ninth bands is opened for a structure with a cylinder radius of r_{zy}=0.0986 a above about n=3.15. In this case, a is the edge length of the normal Cartesian unit cell of the fcc lattice, in which the primitive unit vectors of the fcc lattice coincide with the half-diagonal on the surface (see, for example, Ch. Kittel, Einführung in die Festkörperphysik [Introduction to solid body physics], Oldenbourg Verlag, Munich 1999, page 14).

Furthermore, an enlargement of the bandgap was found between the eighth and ninth bands when parts of a skeleton structure are added to an RVS and, in the process, replace parts of the RVS. In consequence, for example, a bandgap of 6.7% of the mid-frequency of the bandgap can be achieved for the refractive index contrast of n=3.4.

These characteristics open up new application perspectives as photonic bandgap materials for optical circuits and opalescent pigments. For example, lasers with a low threshold energy, optical fiber connections with extremely small possible radii of curvature, optical beam splitters and components for spectral filtering can be produced, or can be produced better, on the basis of these photonic crystals, making use of the large and more easily achievable bandgaps. The simultaneously occurring bandgaps can be used for simultaneous handling of different frequency ranges, for example of two telecommunications windows, in said components. Furthermore, they allow lasers or similar components in which two luminescent species are used, and their luminescence is in each case suppressed by a different bandgap.

The present invention will be explained in more detail using the following example, although it is not restricted to this example.

### EXAMPLE

An inverse TiO₂ opal was produced with the aid of a polystyrene opal (PS opal). This was done using all of the chemicals in the purity as supplied by the manufacturer. As the first step, a PS opal was produced from a dilute suspension of PS particles (Microparticles Company, diameter: 270 nanometers, concentration 1% by weight) by slowly drying at room temperature (approximately 2 weeks in a covered Petri dish). Pieces of the PS opal of about 1-3 mm³ were then subjected to a precursor solution for 10 minutes to 15 days, which led to infiltration of the precursor solution. The precursor solution was typically composed of 80% by volume of titanium isopropoxide (Ti(O-i-C₃H₇)₄, Merck Company) and 20% by volume of ethanol (Merck Company). After the infiltration, the saturated opal pieces were subjected to the environmental air for at least 1 hour (typically several days), in order to allow a reaction with the moisture in the air. The resultant composite material was, finally, calcined in air at 450-700° C.

In the chosen drying conditions (after the precursor infiltration), the resultant samples have a layer structure in the 1-3 mm³ sample pieces. Scanning electron microscope examinations (acceleration voltage 25 kV, 40 000 times electron microscope magnification) of the samples externally virtually always showed an approximately 1-5 μm thick skin of TiO₂ without any regular structures in the size range about 10 nanometers, which may contain isolated pores. This is adjacent to a transitional layer with a thickness of between 1 μm and 50 μm, in which inverse opal structures -with a different structure (RVS, shell structures and skeletons) occur. In this case, fcc lattices, in particular, are observed. The core of the sample particles virtually entirely comprises a skeleton structure, however (see FIG. 2). In this case, the links between the structure crossings are virtually cylindrical, windows formed from these links are polygonal (similar to quadrilaterals, pentagons or hexagons), and there is scarcely any increase in the density of structure crossings in comparison to the cylindrical links. Cylinder radii between 0.04 a and 0.12 a were obtained. This corresponds to positive mean radii of curvature of between 0.08 a and 0.24 a. The edge length a of the conventional unit cell was between 250 and 360 nanometers. On the basis of model calculations, it was possible to verify pseudo bandgaps between the fifth and sixth bands for the structures, with these pseudo bandgaps being larger than in the topologically equivalent RVS. The calculations were carried out using the MIT Photonic Bands (MPB) Software (available at http://ab-initio.mit.edu/mpb), which is known from the prior art (S. G. Johnson and J. D. Joannopoulos in Optics Express 8 (2000) 173). Typically, 10 bands were calculated, with the parameters grid-size (16 16 16), mesh-size 7 and tolerance 10-7.

1. A photonic crystal, whose structure is topologically equivalent to the inverse structure of a predominately convex molding, wherein said crystal:
has a predominately convex structure, and
has a bandgap or pseudo bandgap between a fifth and sixth bands thereof, and/or
has a bandgap or pseudo bandgap between an eighth and ninth bands thereof,
with at least one bandgap or pseudo bandgap being greater than that of the inverse structure of the predominately convex molding, which inverse structure is composed of the same material as the photonic crystal.

2. A method for production of a photonic crystal, said photonic crystal being based on a predominately convex molding, said method comprising the following steps:
(A) penetrating a matrix precursor into cavities in the convex molding;
(B) converting the matrix precursor to a matrix former;
(C) redistributing the matrix precursor/matrix former which is located in the cavities and/or of their intermediate stages while maintaining the topology;
(D) removing the molding.

3. Method as claimed in claim 2, wherein steps (C) and (D) are carried out simultaneously.

4. The method as claimed in claim 2, wherein the matrix former which is introduced does not completely fill the cavities in the molding.

5. The method as claimed in claim 2, wherein the molding (C) is removed by calcination, etching or dissolving.

6. The method as claimed in claim 2, wherein the redistributing (B) is carried out by shrinking during a calcination, drying and/or condensation of the matrix precursor.

7. The method as claimed in claim 6, wherein a calcination is carried out at temperatures from 450 to 700° C. within a time interval of 2 to 12 h.

8. The method as claimed in claim 2, wherein the matrix precursor comprises at least one compound which is selected from the group consisting of:
(i) Metal alkoxides of the formula Mⁿ⁺(⁻OR)ₙ, where R is a branched or unbranched hydrocarbon group with 1 to 12 carbon atoms and M is a metal which is chosen from the groups Ilb, IIIa, IIIb, IVa, IVb and VIIIb in the periodic table of elements; and
(ii) Metal halides and nitrates of the formula Mⁿ⁺(X⁻)ₙ, wherein X is a halide ion chosen from F⁻, Cr⁻, Br⁻ and I⁻ or a nitrate ion (NO₃⁻), and M is a metal chosen from the groups IIb, IIIa, IIIb, IVa, IVb and VIIIb in the periodic table of elements.

9. The method as claimed in claim 8, wherein the matrix precursor comprises at least one compound which is selected from the group consisting of titanium isopropoxide, aluminum chloride, aluminum nitrate, iron (III) chloride and iron (III) nitrate.

10. The method as claimed in claim 2, wherein the matrix precursor has added to it at least one solvent which is selected from the group consisting of methanol, ethanol, 1-propanol, 2-propanol, 1-butanol, 2-butanol and of tert-butanol.

11. The method as claimed in claim 2, with wherein the molding has an opal structure.

12. The method as claimed in claim 2, wherein the molding is composed of polymers or inorganic oxides which are selected from the group of polystyrene, polymethylmethacrylate (PMMA), polydivinylbenzene, poly(styrene-co-divinylbenzene), melamine resins and silicon dioxide.

13. A photonic crystal obtained by a method as claimed in claim 2, characterized wherein this crystal:
has a predominately convex structure, and
has a bandgap or pseudo bandgap between a fifth and sixth bands thereof, and/or
has a bandgap or pseudo bandgap between a eighth and ninth bands thereof.

14. The photonic crystal as claimed in claim 1, said crystal having two or more bandgaps at the same time.

15. The photonic crystal as claimed in claim 1, said crystal comprising cylindrical piece elements linked to one another.

16. (canceled)

17. The photonic crystal as claimed in claim 13, said crystal having two or more bandgaps at the same time.

18. A laser resonator comprising the photonic crystal as claimed in claim 1.

19. A laser resonator comprising the photonic crystal as claimed in claim 13.

20. A matrix for optical waveguides comprising the photonic crystal as claimed in claim 1.

21. A matrix for optical waveguides comprising the photonic crystal as claimed in claim 13.

22. An opalescent pigment comprising the photonic crystal as claimed in claim 1.

23. An opalescent pigment comprising the photonic crystal as claimed in claim 13.

24. A beam splitter comprising the photonic crystal as claimed in claim 1.

25. A beam splitter comprising the photonic crystal as claimed in claim 13.

26. A spectral filter comprising the photonic crystal as claimed in claim 1.

27. A spectral filter comprising the photonic crystal as claimed in claim 13.
